(19) United States
(12) Patent Application Publication
(10) Pub. No.: US 2019/0067176 A1
(43) Pub. Date: Feb. 28, 2019

(54) VOID REDUCTION IN SOLDER JOINTS USING OFF-EUTECTIC SOLDER

(71) Applicant: Intel Corporation, Santa Clara, CA (US)

(72) Inventor: Kabir J. MIRPURI, Scottsdale, AZ (US)

(21) Appl. No.: 16/079,054

(22) PCT Filed: Mar. 22, 2016
(86) PCT No.: PCT/US2016/023593

§ 371 Date: Aug. 22, 2018

(51) Int. Cl. H01L 23/498; H01L 25/00; H01L 23/00

(52) U.S. Cl. CPC H01L 23/49816; H01L 25/50; H01L 2924/15311; H01L 2224/48227; H01L 2225/1058; H01L 24/48

(57) ABSTRACT

Embodiments herein may relate to an apparatus with a package that includes a first substrate soldered to a second substrate via solder comprising an off-eutectic solder material. The off-eutectic solder material may form a joint between the first substrate and the second substrate. The off-eutectic solder material may be any suitable material that melts over a range of temperatures, which may provide a relatively slow collapse of the off-eutectic solder material during a melting process. The relatively slow collapse may provide a sufficient amount of time for gases to escape prior to collapse, and thus, the joint between the first substrate and the second substrate may have less voids compared to joints formed using eutectic solder materials. Other embodiments may be described and/or claimed.

### TECHNICAL FIELD

The present disclosure relates generally to the field of solder joints, and more specifically to solder joints that include an off-eutectic material.

### BACKGROUND

Fluxes alone or solder pastes, which comprise a mixture of flux and solder powder, are widely used in package assemblies for various applications, such as die side capacitor attach, ball grid array (BGA), solder grid array (SGA), and so forth. Voids may be formed in solder joints that are formed during a solder reflow process. Such reflow processes may include the application of heat to the package. Based on the chemical properties of the solder materials, fluxes or solder pastes, chemical reactions may create gases that may become entrapped in the solder material. The chemical reactions may be based on the flux and solder balls alone, or the flux in the solder paste interacting with the solder powder and solder balls and the flux or solder paste interacting with the opposite metallic surface to which the solder joint is being made. As the solder joint formed from the reaction between the solder, fluxes and/or solder paste cools and transitions to a solid state, these gases may not escape from the solder, thereby causing voids to be formed in the solder joint. The formation of these voids may degrade the reliability and/or structural integrity of the joint.

### BRIEF DESCRIPTION OF THE DRAWINGS

Embodiments will be readily understood by the following detailed description in conjunction with the accompanying drawings. To facilitate this description, like reference numerals designate like structural elements.

Embodiments are illustrated by way of example, and not by way of limitation, in the figures of the accompanying drawings.

FIG. 1 is a simplified view of a BGA, in accordance with various embodiments.

FIG. 2 is a phase diagram for various tin-copper alloys, in accordance with various embodiments.

FIG. 3 is a graph showing a void percentage comparison for various tin-silver-copper materials, in accordance with various embodiments.

FIG. 4 is a side, cross-sectional view of a package that includes a BGA and a substrate, in accordance with various embodiments.

FIG. 5 is a side view of an integrated circuit (IC) package that may include the package of FIG. 4, in accordance with various embodiments.

FIG. 6 is an example process for making the package of FIG. 4, in accordance with various embodiments.

FIG. 7 is an example computing device that may include the package of FIG. 2, in accordance with various embodiments.

### DETAILED DESCRIPTION

Embodiments herein may relate to increasing resistance to solder collapse in order to reduce a number of voids created in solder joints. This resistance may be achieved by using an off-eutectic solder metallurgy with sufficiently wide melting range of temperatures.

As used herein “off-eutectic” may indicate a solder material that may melt over a range of temperatures. When the off-eutectic solder material is heated to a temperature within the range of melting temperatures, the off-eutectic solder material may enter a semi-solid and/or semi-liquid state, such that the off-eutectic solder material is not completely molten or completely solid. Furthermore, different phases of an off-eutectic material may solidify at different temperatures, and thus, many off-eutectic materials may solidify over a range of temperatures before becoming completely solid. Because off-eutectic solder materials melt over a range of temperatures, their collapse during melting is relatively slower compared to eutectic solders allowing at least some gases formed during a reflow process to escape from the solder material. Further, since off-eutectic solder materials solidify over another range of temperatures, some gases may escape prior to the solder material completely solidifying. The gases formed during a reflow process, if trapped in the solder while cooling, may cause voids or volatiles in a solder joint. Therefore, forming solder joints using an off-eutectic material may reduce a number of voids in such joints, thereby increasing a structural integrity and/or reliability of the solder joint.

The example embodiments described herein provide for the reduction of voiding within solder joints by modulating solder metallurgy compositions. However, there are several factors other than solder metallurgy composition that tend to cause voiding in solder joints. Some of these factors may include pad surface quality, the type of pad surface finish, pad surface contaminants and/or contamination levels, activity of the flux, reflow temperature, reflow time, and/or other like factors. If one or more of the aforementioned factors are not controlled or managed, then voids may still be created in the solder joints regardless of the type of solder metallurgy composition that is used. Accordingly, the example embodiments described herein assume that the various factors, which may contribute to void formation, are controlled or otherwise managed. Furthermore, the example embodiments may also apply to all known and/or commercially available surface finishes, such as nickel based surface finishes, copper based surface finishes, tin based surface finishes, and/or other like surface finishes.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed on a second layer” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

In various embodiments, the phrase “a first feature formed, deposited, or otherwise disposed on a second feature,” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

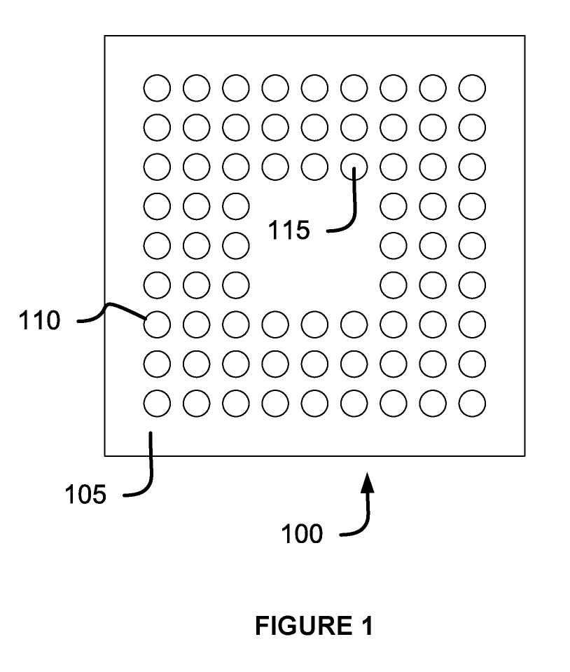

FIG. 1 depicts an example ball grid array (BGA) 100, in accordance with various embodiments. The BGA 100 may include a substrate 105. The substrate 105 may include inner solder balls 115 and outer solder balls 110 (collectively referred to herein as solder balls 110 and 115.) In embodiments herein, the solder balls 110 and 115 may be made of an off-eutectic material. In embodiments herein, a tin-copper (Sn—Cu) material may be discussed, but in other embodiments the off-eutectic material may be or include a tin/silver/copper (SAC) material. In some embodiments, the off-eutectic material may be doped with a dopant material such as nickel (Ni) and/or some other material. In some embodiments, the substrate 105 may include or be formed of some thermally and/or electrically neutral material such as fiberglass, epoxy, silicon, or some other material. In some embodiments, the solder balls 110 and 115 may also be referred to as solder “bumps” and the like. Generally, as used herein, a solder ball or solder bump may refer to the solder material itself, either in its pre- or post-reflow state. A solder joint (also referred to as a “joint” herein) may generally refer to a post-reflow construct that includes a solder ball coupled with two substrates, as described in further detail below.

The joint may comprise solder balls and flux or solder paste consisting of solder material and a flux material. The flux material may include one or more organic materials, such as acids, amines, polymers, thixotropic agents, hardening agents, solvents, rosins, chelating agents, and the like. Upon heating the solder paste or the flux material, the organic species start volatilizing as a function of their boiling point. The solder paste may be a suitable mixture of one or more fluxes and solder particles ranging in size from several angstroms to several hundred microns. The solder composition of the solder particles can be a single element like Sn or a mix of different elements as in a solder alloy.

The off-eutectic solder materials discussed herein may melt over a relatively broad range of temperatures. When the off-eutectic solder materials are heated within this range of temperatures, the off-eutectic solder materials may enter a semi-solid or semi-liquid state. In some embodiments, the off-eutectic solder materials may have a copper content and/or silver content of approximately 1 wt. %. It has been found through experimentation that, by forming an off-eutectic solder material to have a copper content of approximately 1 wt. % and/or a silver content of approximately 1 wt. %, it may be possible to achieve low voiding performance without substantially compromising mechanical properties of the joint. This is because the conventionally used Sn—Cu or SAC solder materials are eutectic materials, and therefore, have a melting point at a single temperature. For example, Sn—Cu solder materials having a copper content of 0.7 wt. % may typically melt at 227 degrees Celsius (° C.), SAC materials having a silver content of 3 wt. % and a copper content of 0.5 wt. % (also referred to as “SAC305”) may typically melt at 218° C., and SAC materials having a silver content of 4 wt. % and a copper content of 0.5 wt. % (also referred to as “SAC405”) may typically melt at 218° C. These eutectic solder materials may melt completely as soon as the temperature reaches that material's melting point, for example, 218° C. for SAC405 or 218° C. for SAC305. Once the eutectic solder materials reach their melting point during a reflow process, the eutectic solder material may collapse relatively quickly, which may result in gases being trapped within the melted eutectic solder material. These entrapped gases may result in the creation of voids or volatiles (also referred to as “voiding”) when the eutectic solder material cools to a temperature below the melting point or otherwise enters a solid phase. As a consequence, joints formed by such a reflow process may include voids. The formation of these voids may degrade the reliability and/or structural integrity of the joint.

In various embodiments, solder balls 110 and 115 may be formed of an off-eutectic solder material or any solder material that exhibits off-eutectic properties. In embodiments, the off-eutectic solder material may be an alloy made of the one or more of copper (Cu), tin (Sn), silver (Ag), bismuth (Bi), indium (In), lead (Pb), and zinc (Zn). In some embodiments, the off-eutectic solder material may be an alloy that includes one or more other elements and/or materials not cited herein, such as those commonly used in the art. In some embodiments, the off-eutectic solder material may be doped with a dopant including one or more of Cu, Sn, Ag, Bi, In, Pb, Zn, nickel (Ni), chromium (Cr), titanium (Ti), yettrium (Ye), zirconium (Zr), antimony (Sb), strontium (Sr), cobalt (Co), iron (Fe), manganese (Mn), molybdeum (Mo), tungsten (W), platinum (Pt), gold (Au), magnesium (Mg), cerium (Ce), and lanthanum (La). In some embodiments, the dopant may include one or more other elements and/or materials not cited herein, such as those commonly used in the art.

Off-eutectic materials may not melt at a single temperature, but rather these materials may melt over a range of temperatures (also referred to as a “range of melting temperatures,” “melting temperature range,” “melting range of temperatures,” and the like). When an off-eutectic material is at a temperature that is above the range of melting temperatures, the off-eutectic material may be in a molten state. Additionally, when an off-eutectic material is at a temperature that is below the range of melting temperatures, the off-eutectic material may be in a solid state. Since off-eutectic materials melt over a range of temperatures, the melting of these materials may be relatively slow (or appear to be delayed) in comparison to the melting of eutectic materials. The relatively slow melting or collapse of the off-eutectic solder materials during the melting process may provide a sufficient amount of time for volatile species to escape prior to collapse. Furthermore, off-eutectic materials may not solidify at a single temperature, but rather these materials may solidify over a range of temperatures, and thus, the solidification of these materials may be relatively slow (or appear to be delayed) in comparison to the solidification of eutectic materials. In addition to the relatively slow melting, the relatively slow solidification may also allow at least some volatile species to escape while the solder material cools. As a consequence, joints formed using an off-eutectic material may have less voids compared to joints formed using eutectic solder materials. Moreover, joints formed using such off-eutectic solder materials may include less voids while maintaining a same or similar mechanical properties as joints formed using eutectic solder materials.

In some embodiments, solder balls 110 and 115 may be formed of an off-eutectic Sn—Ag—Cu (SAC) material, such as an SAC material having a silver content of 1 wt. % and a copper content of 0.5 wt. % (also referred to as “SAC105”), and having a range of melting temperatures of that is between approximately 217° C. and approximately 228° C. In some embodiments, solder balls 110 and 115 may be formed of an SAC material having a copper content of 0.7 wt. % (also referred to as “SAC107”), and having a range of melting temperatures that is between approximately 217° C. and approximately 224° C. In some embodiments, solder balls 110 and 115 may be formed of an SAC material having a silver content of 1.2 wt. % and a copper content of 0.5 wt. % (also referred to as “SAC1205”), and having a range of melting temperatures that is between approximately 218° C. and approximately 224° C. In embodiments where the off-eutectic material is SAC1205, the off-eutectic material may be doped with a nickel (Ni) dopant material. In other embodiments, solder balls 110 and 115 may be formed of an off-eutectic Sn—Cu material, such as an Sn—Cu material having a Cu content of 1 wt. %, and having a range of melting temperatures between 227° C. and 240° C. In various embodiments, solder balls 110 and 115 may be formed of any composition having more or less than 0.7% Cu and that has a melting temperature lower than approximately 250° C. to 260° C., which may comply with commercial ball attach or surface mount processes in assembly packaging.

In various embodiments, the range of melting temperatures may include a range of liquidus temperatures and a range of solidus temperatures. In such embodiments, when the off-eutectic material is at a temperature above a greatest temperature of the range of liquidus temperatures, the off-eutectic material may be completely liquid. Additionally, the off-eutectic material may be completely solid when the off-eutectic material is at a temperature below a lowest temperature of the range of solidus temperatures.

Other examples of off-eutectic materials that may be used as solder balls 110 and 115 may include a material having approximately 60-80 wt. % of Sn and approximately 20-40 wt. % of Zn, and having a range of liquidus temperatures that is between approximately 225-300° C. and range of solidus temperatures that is between approximately 197-200° C. By way of another example, the off-eutectic material may be a material having approximately 90-98 wt. % of Sn and approximately 2-10 wt. % of Zn, and having a range of liquidus temperatures that is between approximately 220-230° C. and a range of solidus temperatures that is between approximately 197-200° C. By way of another example, the off-eutectic material may be a material having approximately 60-80 wt. % of Sn and approximately 20-50 wt. % of Bi, and having a range of liquidus temperatures that is between approximately 150-200° C. and range of solidus temperatures that is between approximately 137-139° C. By way of another example, the off-eutectic material may be a material having approximately 10-40 wt. % of Sn and approximately 60-90 wt. % of Bi, and having a range of liquidus temperatures that is between approximately 150-250° C. and a range of solidus temperatures that is between approximately 137-139° C. By way of another example, the off-eutectic material may be a material having approximately 20-50 wt. % of Sn and approximately 50-80 wt. % of Pb, and having a range of liquidus temperatures that is between approximately 200-275° C. and a range of solidus temperatures that is between approximately 182-184° C. By way of another example, the off-eutectic material may be a material having approximately 70-90 wt. % of Sn and approximately 10-30 wt. % of Pb, and having a range of liquidus temperatures that is between approximately 200-225° C. and a range of solidus temperatures that is between approximately 182-184° C. By way of another example, the off-eutectic material may be a material having approximately 60-85 wt. % of Sn and approximately 15-40% of In, and having a range of liquidus temperatures that is between approximately 135-200° C. and a range of solidus temperatures that is between approximately 117-119° C. By way of another example, the off-eutectic material may be a material having approximately 90-95 wt. % of Sn and approximately 5-10 wt. % of Ag, and having a range of liquidus temperatures that is between approximately 230-300° C. and a range of solidus temperatures that is between approximately 220-222° C. By way of another example, the off-eutectic material may be a material having approximately 95-97 wt. % of Sn and approximately 3-5 wt. % of Cu, and having a range of liquidus temperatures that is between approximately 250-300° C. and a range of solidus temperatures that is between approximately 226-228° C. By way of another example, the off-eutectic material may be a material having approximately 60-90 wt. % of Bi and approximately 10-40 wt. % of In, and having a range of liquidus temperatures that is between approximately 150-250° C. and a range of solidus temperatures that is between approximately 109-111° C.

The aforementioned off-eutectic materials are intended merely as illustrative examples, and in other embodiments, the off-eutectic solder material may have a different composition than those recited herein. Additionally, the range of liquidus temperatures and the range of solidus temperatures may be dependent on the particular combination of wt. % of the aforementioned elements. Therefore, different combinations of wt. % within the aforementioned compositional ranges may provide different liquidus temperature ranges and/or different solidus temperature ranges. Furthermore, the aforementioned temperatures are based on upper limits for traditional ball attach reflow processes and board surface mount (SMT) reflow processes used in electronic assembly packaging. In embodiments where processes different from electronic assembly packaging are used, the aforementioned compositions may have higher temperature range limits than previously specified. Moreover, although the previous examples describe solder materials having two elements (binary), which are not eutectic in nature, the example embodiments may apply to solder materials having more than two elements. For example, embodiments described herein may apply to solder materials having more than two elements, such as off-eutectic materials having three elements (ternary), off-eutectic materials having four elements (quaternary), and the like. In other embodiments, the solder material may have five, six, or more elements as long as such compositions are off-eutectic or exhibit off-eutectic characteristics.

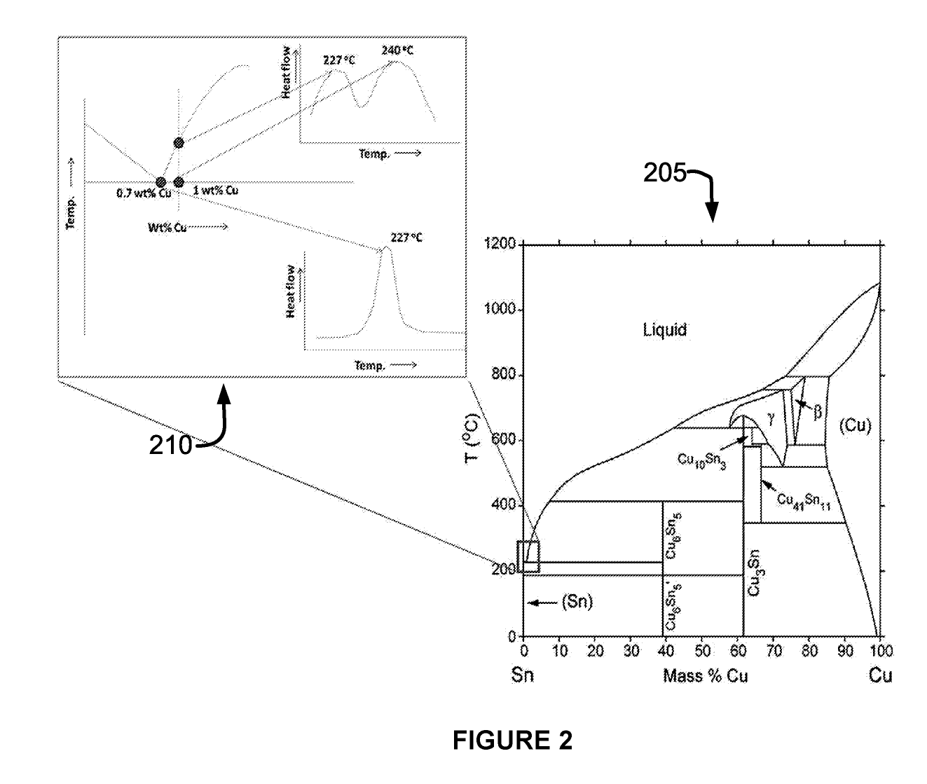

FIG. 2 depicts an example phase diagram 200 of Sn—Cu solder materials. In the graph 205, the x axis may show the percentage of Cu and/or Sn in various Sn—Cu solder materials. The y axis may show the temperature in degrees Celsius. The area below the line 210 may indicate portions of the phase diagram where the different elements are present in solid or semi-solid form, while the area above the line 210 may indicate portions of the phase diagram where the different elements are present in liquid form. Further, the area above the line 210 may indicate a liquidus temperature for each Sn—Cu material. The region of phase diagram 200 designated with γ may represent a gamma phase, and the region of phase diagram 200 designated with β may represent a beta phase.

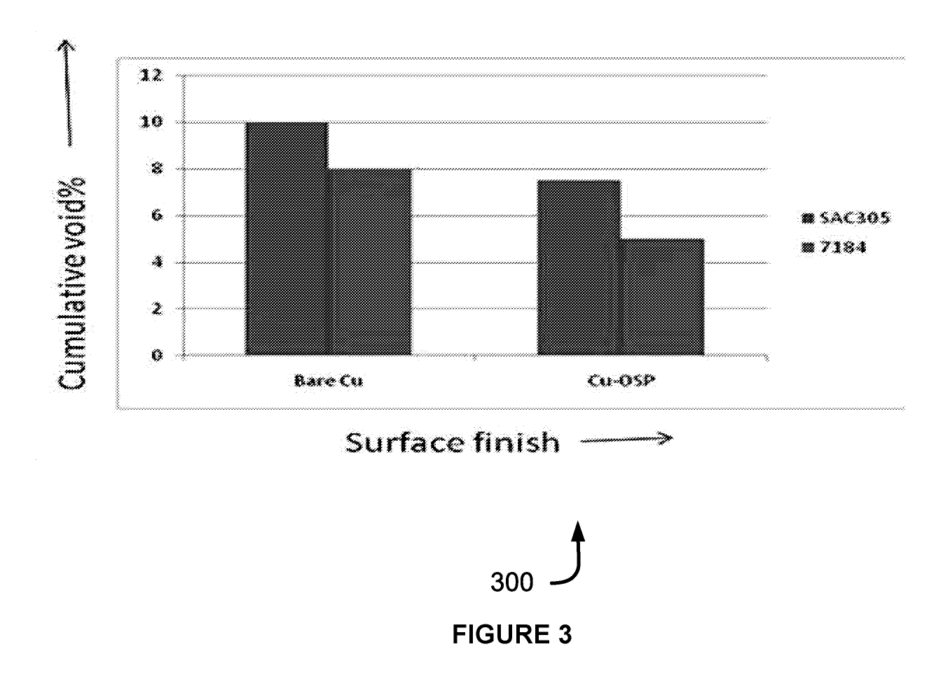

The graph 215 shows melting temperatures for Sn—Cu solder materials based on weight percentage (wt. %) of Cu. The x axis may show the wt. % of Cu in the Sn—Cu solder material and the y axis may show the temperature in degrees Celsius. As shown, when the Sn—Cu solder material has a copper content of 1 wt. %, the Sn—Cu solder material may melt over a range of temperatures between 227° C. and 240° C. The Sn—Cu solder material having a copper content of 1 wt. % may be considered an off-eutectic material. By contrast, a Sn—Cu solder material with a copper content of 0.7 wt. % may have a single melting point of 227° C. The Sn—Cu solder material having a copper content of 0.7 wt. % may be considered a eutectic material. Accordingly, by increasing the Cu content of an Sn—Cu solder material from 0.7 wt. % to 1.0 wt. %, it may be possible to achieve low voiding performance as is shown by FIG. 3, for example.

FIG. 3 depicts a graph 300 showing a void percentage (%) comparison for SAC305 and SAC1205 doped with nickel (Ni) in accordance with various embodiments. As shown, the eutectic material SAC305 has a higher void % than the off-eutectic SAC1205 for both a surface finish of bare copper (Bare-Cu) and surface finish of copper with organic surface preservative (Cu-OSP). SAC1205 doped with Ni may have a lower void % than SAC305 since SAC1205 has a melting range of approximately 218-224° C., which may be a broader melting range than SAC305. Since SAC1205 doped with Ni may have a broader melting range than SAC305, SAC1205 may provide more time for gases to escape from the solder material before collapse thereby reducing a number of voids in the joints formed using the SAC1205.

Furthermore, by using an off-eutectic solder material it may be possible to achieve low voiding performance without significantly altering the mechanical properties of a joint formed therefrom. These mechanical properties may include a shear strength, a tensile strength, a tensile elongation, shock performance, a hardness, and/or any other mechanical property. For example, an off-eutectic solder material may maintain a same or similar shear strength if changes in the elemental concentration or composition of the off-eutectic solder material is not too substantial. This means that an off-eutectic solder with a slightly greater copper content than other Sn—Cu based solder materials may maintain a same or similar shear strength as the other Sn—Cu based solder materials. By contrast, Sn—Cu solders with little to no copper may have less the shear strength than off-eutectic solder materials with a slightly greater copper content. Thus, off-eutectic solder materials with small changes in elemental composition may maintain a same or similar shear strength as eutectic solders. For such small changes, the mechanical properties will not change much even after being subjected to multiple reflow cycles. For example, as shown in table 1 below, the two solders, SAC0307 and SAC0807 vary only by a relatively minor 0.5 wt. % of Ag resulting in a minimal change in their mechanical properties.

TABLE 1

| | | Tensile | |
|---|---|---|---|
| | Tensile Strength | Elongation | Brinell Hardness |
| Solder Alloy | at Break (kgf/cm²) | at Break (%) | (HB) |
| Sn99Ag0.3Cu0.7 | 300 | 22 | 14 |
| (SAC0307) | | | |
| Sn99Ag0.8Cu0.7 | 310 | 21 | 16 |
| (SAC0807) | | | |

Additionally, in some cases, various packaging processes may be used to remedy metallurgical shortcomings of off-eutectic solder materials. For example, some off-eutectic Sn—Cu materials may be slightly less ductile than eutectic Sn—Cu materials. However, in various embodiments, a wafer level underfill (WLUF) technology and/or a photoresist material may be used during a package construction process to compensate for the decreased shock resistance arising due to the lack of ductility of an off-eutectic solder material because WLUF and/or a photoresist may help cushion away higher stress thus lowering the stress within the solder joint. Furthermore, the off-eutectic solder materials of the example embodiments may have better shock performance as compared to convention eutectic solder materials since the off-eutectic solder materials have a lower silver content than conventional eutectic solder material (e.g., SAC105 with 1 wt. % Ag typically has better shock performance than SAC405 with 4 wt. % Ag).

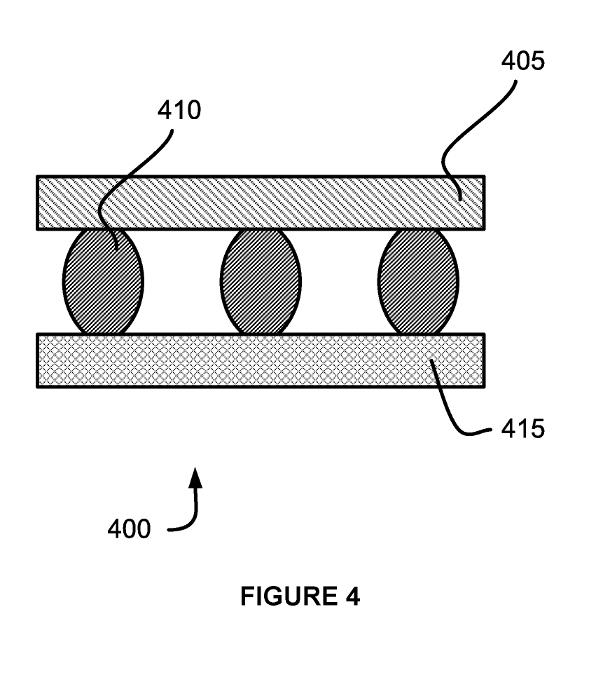

FIG. 4 depicts an example of a package 400 that may include a plurality of solder joints. In embodiments, a BGA such as BGA 100 may include a first substrate 405 and a plurality of solder balls 410 that may be similar to substrate 105 and solder balls 110 and 115. The plurality of solder balls 410 may be made of an off-eutectic material. In embodiments, the solder balls 410 and/or package 400 may have been heated during a reflow process to a temperature that is above a melting and/or a liquidus range of temperatures of the solder balls 410, and a relatively slow melting or collapsing of the solder balls 410 may allow at least some volatiles to escape. In embodiments, this heating may have occurred during a reflow process or during some other process. Once reflowed, the solder balls 410 may have been placed against a second substrate 415 and allowed to cool, thereby forming one or more joints. The solidification during cooling process of the solder balls 410 may be slower than if the solder balls 410 were made of a eutectic material. Thus, as the solder balls 410 cool and transition to a solid state, volatiles and/or gases created during the heating process may escape from the solder, thereby reducing an amount of voids in the solder joint formed by the solder balls 410. In embodiments, the second substrate 415 may be composed of a material similar to that of substrate 105 as described above. In some embodiments, a surface of the first substrate 405 and/or the second substrate 415 may be coated with a WLUF material and/or a photoresist material prior to the heating. In some embodiments, one or both of substrates 405 and/or 415 may have one or more pads, traces, and/or vias that may carry electrical signals to or from the solder balls 410 such that signals can be passed from first substrate 405 to second substrate 415, or vice versa, via solder balls 410.

Example embodiments described herein may provide significant advantages over legacy systems. Specifically, because the solder balls 410 may be formed of an off-eutectic material, such as any one or more of the off-eutectic materials described previously, the joints formed using solder balls 410 may have less voids than joints formed using convention eutectic solder materials, such as SAC305, SAC405, and the like.

Although FIG. 4 depicts an example package 400 including a plurality of solder joints, wherein the first substrate 405 and the second substrate 415 are connected to one another by way of a plurality of solder balls 410, the example embodiments are not limited thereto. In other embodiments, the package 400 may be a Solder Grid Array (SGA) package, a Solder on Die (SoD) package, or any other suitable package. In embodiments where the package 400 is an SGA package, package 400 may include joints formed by solely melting the solder paste without using any solder balls to form the joint. In that regard the eutectic or off-eutectic composition may refer to the solder particle metallurgy used in the paste.

In embodiments where the package 400 is a SoD package, the first substrate 405 may be soldered to the second substrate 415 via one or more solder-Cu bump connections, wherein each of the one or more solder-Cu bump connections may form a corresponding joint between the first substrate 405 and the second substrate 415. The solder-Cu bump connections may be formed by performing a solder paste printing (SPP) process on one or more silicon-copper pillar bumps (also referred to as “Si—Cu pillar bumps” or “Si—Cu pillars”). In some embodiments, when the package 400 is part of a first level interconnect (FLI) joint, the SPP process may include printing or otherwise applying additional solder on the Cu bump connections in addition to the off-eutectic solder material to be printed on the substrates 405 and 415. This additional solder may be the off-eutectic solder material as discussed herein or some other suitable solder material.

In embodiments where the package 400 is an SGA package, the first substrate 405 may be soldered to the second substrate 415 via one or more conductive bumps (also referred to as “SGA bumps”), which may be disposed on the first substrate 405. The first substrate 405 may be placed on the second substrate 415 and soldered thereto using one or more of the off-eutectic solder materials described herein.

In some embodiments, the substrate 405 may be, for example, a substrate of a client processor, a server processor, a dynamic random access memory (DRAM), a package on package (PoP), or some other type of BGA package, SGA package, or SoD package. In embodiments, the second substrate 415 may be a substrate of, for example, a printed circuit board (PCT) like a motherboard, an interposer, or some other type of package.

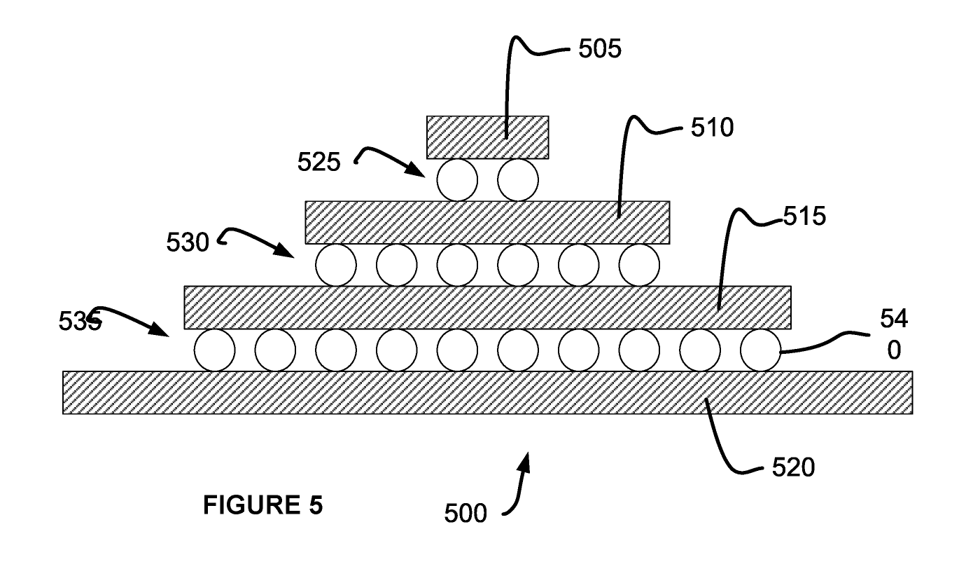

FIG. 5 depicts an example of an integrated circuit (IC) package 500 that may include one or more BGA packages such as BGA package 100. Specifically, the IC package 500 may include a die 505, a patch 510, an interposer 515, and/or a motherboard 520. In embodiments, the die 505 may be coupled with the patch 510 via one or more solder joints 525. In this embodiment, the die 505 may be considered to be the substrate 405 and the patch 510 may be considered to be the second substrate 415. Additionally or alternatively, the patch 510 may be coupled with the interposer 515 via one or more solder joints 530. In this embodiment, the patch 510 may be considered to be the substrate 405 and the interposer 515 may be considered to be the second substrate 415. Additionally or alternatively, the interposer 515 may be coupled with the motherboard 520 via one or more solder joints 535. In this embodiment, the interposer 515 may be considered to be the substrate 405 and the motherboard 520 may be considered to be the second substrate 415. In embodiments, the solder joints 525, 530, and 535 may include one or more solder balls 540 that may be similar to solder ball 410. In some embodiments, the solder joints 525 may be referred to as a first level interconnect (FLI). In some embodiments the solder joints 530 may be referred to as a mid-level interconnect (MLI). In some embodiments, the solder joints 535 may be referred to as a second level interconnect (SLI). In some embodiments, the one or more solder balls 540 forming each of the solder joints 525, 530, and 535 may be the same off-eutectic solder material, such as one of the previously described off-eutectic materials. In other embodiments, the one or more solder balls 540 forming each of the solder joints 525, 530, and 535 may be formed of a different off-eutectic solder material. For example, in some embodiments the one or more solder balls 540 of the solder joint 525 may be formed of SAC105 or SAC107 while the one or more solder balls 540 of the joints 530 and 535 may be formed of SAC1205 doped with a nickel doping material. Example embodiments include forming the one or more solder balls 540 forming each of the solder joints 525, 530, and 535 according to any combination of off-eutectic solder materials as described herein.

Although FIG. 5 depicts an example package 500 including a BGA including one or more solder balls 540 forming each of the solder joints 525, 530, and 535, the example embodiments are not limited thereto. In other embodiments, the package 500 may be an SGA package, an SoD package, or any other suitable package. In such embodiments, the die 505, patch 510, interposer 515, and/or motherboard 520 may be attached to one another according to a variety of suitable configurations including, a flip-chip configuration, wirebonding, and the like.

It will be recognized that the relative sizes of the die 505, patch 510, interposer 515, and motherboard 520 are intended merely as illustrative examples in FIG. 5, and in other boards the size of the various elements may be different. Additionally, in some embodiments certain elements such as the patch 510 and/or interposer 515 may not be present. In some embodiments, the number of solder balls in the solder joints 525, 430, and/or 435 may be different than what is illustrated in FIGS. 4-5.

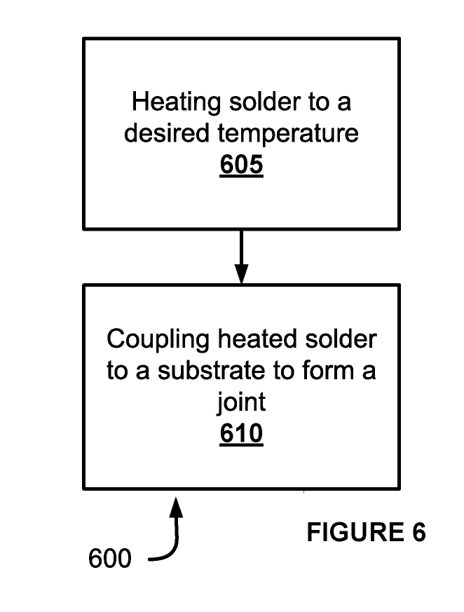

FIG. 6 depicts an example process 600 for constructing a package such as package 400. Referring to FIG. 6, at operation 605 may include heating a solder formed of an off-eutectic solder material to a desired temperature. This heating may occur, for example, during a reflow process. In embodiments, the desired temperature may be greater than equal to a greatest temperature of a melting range of temperatures of the off-eutectic solder material. In embodiments, the off-eutectic solder material may provide a relatively slow collapse of the off-eutectic solder material during the heating process. The relatively slow collapse may provide a sufficient amount of time for gases (formed by way of chemical reactions during the heating process) to escape prior to collapse. In some embodiments, the solder may include a plurality of solder balls that are formed of the off-eutectic solder material. The solder balls may be solder balls of a BGA package, such as BGA package 100. For example, in some embodiments the solder balls may be similar to solder balls 110, 115, or 410, and the BGA package may include a substrate such as substrate 105 or 305. In other embodiments, an SPP process may be performed to place the solder on one or more Si—Cu pillar bumps. In other embodiments, the solder may be placed on one or more SGA bumps that are disposed on a substrate, such as the first substrate 405.

At operation 610, the process 600 may further include coupling, while the off-eutectic solder material is at or about the desired temperature, the solder to a substrate to form a joint. The coupling may result in forming a plurality of solder joints between the BGA package and a substrate such as second substrate 415 or forming another like joint as described herein. In embodiments, after the coupling, the off-eutectic solder material may provide a relatively slow cooling of the off-eutectic solder material during a cooling process. The relatively slow cooling may provide a sufficient amount of time for gases (formed by way of a chemical reaction during the heating process) to escape prior to solidification. Thus, the plurality of solder joints between the package and a substrate may have less voids when compared to joints formed using eutectic solder materials.

The previously described temperature ranges are intended to be examples of an off-eutectic solder materials, and in other embodiments different temperature ranges may be desirable dependent on the type of solder alloy used, the type or amount of dopant present in the solder material, the different ratios of elements within the alloy itself, the size or width of the various solder balls or solder joints, the desired properties of the solder joint, the range of melting temperatures, range of liquidus temperatures and/or range of solidus temperatures of the off-eutectic solder material, the desired reflow temperatures for the system in consideration, and/or one or more additional or alternative parameters. It has been found through experimentation that, with a small change in the elemental composition of a solder material, it is possible to impart off-eutectic nature to the solder joint without causing any substantial changes in the mechanical properties of the solder. Further, although not shown by FIG. 6, the process 600 may further include coating a surface of the package with a wafer-level underfill (WLUF) material prior to the heating at operation 605 and/or performing another heating process, such as a solder reflow process, after the coupling at operation 610. Such additional WLUF like technology could be adopted where the off-eutectic solder material may alter the mechanical properties of the joint. The WLUF like material can, in that case, provide protection to the silicon dielectric layer, for example.

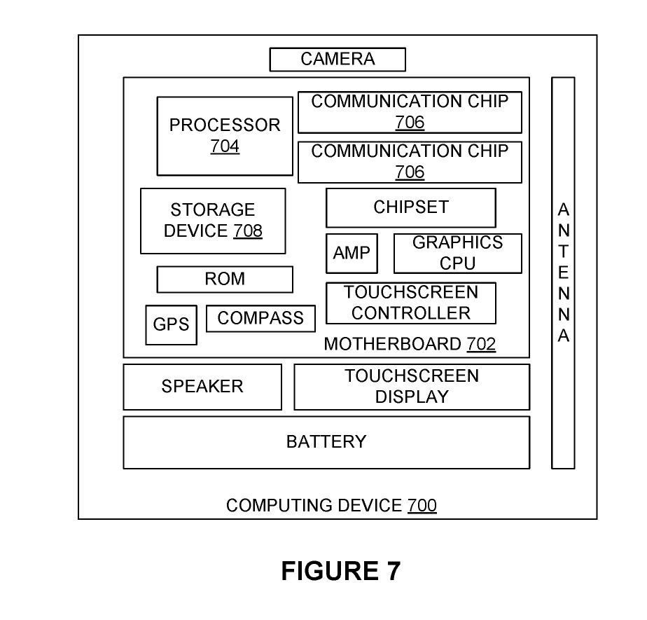

Embodiments of the present disclosure may be implemented into a system using any interposers, IC packages, or IC package structures that may benefit from the off-eutectic solder material and manufacturing techniques disclosed herein. FIG. 7 schematically illustrates a computing device 700, in accordance with some implementations, which may include one or more BGAs such as BGA 100, packages such as package 400, and/or IC packages such as IC package 500. For example, the substrates 105 and/or 405, or the die 505 may include a storage device 708, a processor 704, and/or a communication chip 706 of the computing device 700 (discussed below).

The computing device 700 may be, for example, a mobile communication device or a desktop or rack-based computing device. The computing device 700 may house a board such as a motherboard 702. In embodiments, the motherboard 702 may be similar to second substrate 415 and/or motherboard 520. The motherboard 702 may include a number of components, including (but not limited to) a processor 704 and at least one communication chip 706. Any of the components discussed herein with reference to the computing device 700 may be arranged in or coupled with a BGA such as BGA 100, or incorporated into package 400 or IC package 500 as discussed herein. In further implementations, the communication chip 706 may be part of the processor 704.

The computing device 700 may include a storage device 708. In some embodiments, the storage device 708 may include one or more solid state drives. Examples of storage devices that may be included in the storage device 708 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 700 may include other components that may or may not be physically and electrically coupled to the motherboard 702. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 706 and the antenna may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wide region (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 706 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 706 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 706 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 706 may operate in accordance with other wireless protocols in other embodiments.

The computing device 700 may include a plurality of communication chips 706. For instance, a first communication chip 706 may be dedicated to shorter range wireless communications such as Wi-Fi and Bluetooth, and a second communication chip 706 may be dedicated to longer range wireless communications such as GPS, EDGE, GPRS, CDMA, WiMAX, LTE, EV-DO, and others. In some embodiments, the communication chip 706 may support wired communications. For example, the computing device 700 may include one or more wired servers.

The processor 704 and/or the communication chip 706 of the computing device 700 may include one or more dies or other components in an IC package. Such an IC package may be coupled with an interposer or another package using any of the techniques disclosed herein. The term “processor” may refer to any device or portion of a device that processes electronic data from registers and/or memory to transform that electronic data into other electronic data that may be stored in registers and/or memory.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data. In some embodiments, the recessed conductive contacts disclosed herein may be implemented in a high-performance computing device.

The following paragraphs provide examples of various ones of the embodiments disclosed herein.

Example 1 may include an apparatus comprising: a first substrate; and a package that includes a second substrate soldered to the first substrate via solder comprising an off-eutectic material such that the solder forms a joint between the first substrate and the second substrate, wherein the off-eutectic material is a material that melts over a range of melting temperatures. When the off-eutectic material is at a temperature that is above a greatest temperature of the range of melting temperatures, the off-eutectic material is in a molten state. When an off-material is at a temperature that is below a lowest temperature of the range of melting temperatures, the off-eutectic material is in a solid state.

Example 2 may include the apparatus of example 1 and/or one or more other examples herein, wherein the off-eutectic material includes one or more of copper (Cu), tin (Sn), silver (Ag), bismuth (Bi), indium (In), lead (Pb), and zinc (Zn).

Example 3 may include the apparatus of example 2 and/or one or more other examples herein, wherein the off-eutectic material includes a dopant, wherein the dopant includes one or more of Cu, Sn, Ag, Bi, In, Pb, Zn, nickel (Ni), chromium (Cr), titanium (Ti), yettrium (Ye), zirconium (Zr), antimony (Sb), strontium (Sr), cobalt (Co), iron (Fe), manganese (Mn), molybdeum (Mo), tungsten (W), platinum (Pt), gold (Au), magnesium (Mg), cerium (Ce), and lanthanum (La). In some examples, the dopant may include one or more other elements and/or materials not cited herein.

Example 4 may include the apparatus of example 1 and/or one or more other examples herein, wherein the second substrate was soldered to the first substrate at a temperature greater than a greatest temperature of the range of melting temperatures.

Example 5 may include the apparatus of example 1 and/or one or more other examples herein, wherein the off-eutectic material includes approximately 0.5-1.5% Ag and approximately 0.1-0.7% Cu, and wherein a lowest temperature of the range of melting temperatures is between approximately 215-220 degrees Celsius and a greatest temperature of the range of melting temperatures is between approximately 222-230 degrees Celsius.

Example 6 may include the apparatus of example 5 and/or one or more other examples herein, wherein the off-eutectic material is doped with Ni.

Example 7 may include the apparatus of example 1 and/or one or more other examples herein, wherein the off-eutectic material includes more or less than approximately 0.7% Cu, and wherein a lowest temperature of the range of melting temperatures is between approximately 225-229 degrees Celsius and a greatest temperature of the range of melting temperatures is between approximately 238-242 degrees Celsius.

Example 8 may include the apparatus of example 1 and/or one or more other examples herein, wherein the off-eutectic material comprises a material having a greatest temperature of the range of melting temperatures that is less than or equal to approximately 250-260 degrees Celsius.

Example 9 may include the apparatus of example 1 and/or one or more other examples herein, wherein the melting range of temperatures includes a liquidus range of temperatures and a solidus range of temperatures, wherein the off-eutectic material is completely liquid when the off-eutectic material is at a temperature above a greatest temperature of the range of liquidus temperatures and the off-eutectic material is completely solid when the off-eutectic material is at a temperature below a lowest temperature of the range of solidus temperatures.

Example 10 may include the apparatus of example 9 and/or one or more other examples herein, wherein the off-eutectic material comprises approximately 60-80% Sn and approximately 20-40% Zn, wherein a lowest temperature of the range of liquidus temperatures is between approximately 225-230 degrees Celsius and a greatest temperature of the range of liquidus temperatures is between approximately 290-300 degrees Celsius, and wherein the off-eutectic material further comprises a range of solidus temperatures between approximately 197-200 degrees Celsius.

Example 11 may include the apparatus of example 9 and/or one or more other examples herein, wherein the off-eutectic material comprises approximately 90-98% Sn and approximately 2-10% Zn, wherein a lowest temperature of the range of liquidus temperatures is between approximately 220-225 degrees Celsius and a greatest temperature of the range of liquidus temperatures is between approximately 227-230 degrees Celsius, and wherein the off-eutectic material further comprises a range of solidus temperatures between approximately 197-200 degrees Celsius.

Example 12 may include the apparatus of example 9 and/or one or more other examples herein, wherein the off-eutectic material comprises approximately 60-80% Sn and approximately 20-50% Bi, wherein a lowest temperature of the range of liquidus temperatures is between approximately 150-160 degrees Celsius and a greatest temperature of the range of liquidus temperatures is between approximately 190-200 degrees Celsius, and wherein the off-eutectic material further comprises a range of solidus temperatures between approximately 137-139 degrees Celsius.

Example 13 may include the apparatus of example 9 and/or one or more other examples herein, wherein the off-eutectic material comprises approximately 10-40% Sn and approximately 60-90% Bi, wherein a lowest temperature of the range of liquidus temperatures is between approximately 150-160 degrees Celsius and a greatest temperature of the range of liquidus temperatures is between approximately 240-250 degrees Celsius, and wherein the off-eutectic material further comprises a range of solidus temperatures between approximately 137-139 degrees Celsius.

Example 14 may include the apparatus of example 9 and/or one or more other examples herein, wherein the off-eutectic material comprises approximately 20-50% Sn and approximately 50-80% Pb, wherein a lowest temperature of the range of liquidus temperatures is between approximately 200-210 degrees Celsius and a greatest temperature of the range of liquidus temperatures is between approximately 260-275 degrees Celsius, and wherein the off-eutectic material further comprises a range of solidus temperatures between approximately 182-184 degrees Celsius.

Example 15 may include the apparatus of example 9 and/or one or more other examples herein, wherein the off-eutectic material comprises approximately 70-90% Sn and approximately 10-30% Pb wherein a lowest temperature of the range of liquidus temperatures is between approximately 200-210 degrees Celsius and a greatest temperature of the range of liquidus temperatures is between approximately 215-225 degrees Celsius, and wherein the off-eutectic material further comprises a range of solidus temperatures between approximately 182-184 degrees Celsius.

Example 16 may include the apparatus of example 9 and/or one or more other examples herein, wherein the off-eutectic material comprises approximately 60-85% Sn and approximately 15-40% In, wherein a lowest temperature of the range of liquidus temperatures is between approximately 135-145 degrees Celsius and a greatest temperature of the range of liquidus temperatures is between approximately 190-200 degrees Celsius, and wherein the off-eutectic material further comprises a range of solidus temperatures between approximately 117-119 degrees Celsius.

Example 17 may include the apparatus of example 9 and/or one or more other examples herein, wherein the off-eutectic material comprises approximately 90-95% Sn and approximately 5-10% Ag, wherein a lowest temperature of the range of liquidus temperatures is between approximately 230-240 degrees Celsius and a greatest temperature of the range of liquidus temperatures is between approximately 290-300 degrees Celsius, and wherein the off-eutectic material further comprises a range of solidus temperatures between approximately 220-222 degrees Celsius.

Example 18 may include the apparatus of example 9 and/or one or more other examples herein, wherein the off-eutectic material comprises approximately 95-97% Sn and approximately 3-5% Cu, wherein a lowest temperature of the range of liquidus temperatures is between approximately 250-260 degrees Celsius and a greatest temperature of the range of liquidus temperatures is between approximately 290-300 degrees Celsius, and wherein the off-eutectic material further comprises a range of solidus temperatures between approximately 226-228 degrees Celsius.

Example 19 may include the apparatus of example 9 and/or one or more other examples herein, wherein the off-eutectic material comprises approximately 60-90% Bi and approximately 10-40% In wherein a lowest temperature of the range of liquidus temperatures is between approximately 150-160 degrees Celsius and a greatest temperature of the range of liquidus temperatures is between approximately 240-250 degrees Celsius, and wherein the off-eutectic material further comprises a range of solidus temperatures between approximately 109-111 degrees Celsius.

Example 20 may include the apparatus of any one of examples 1-19 and/or one or more other examples herein, wherein the solder joint includes a wafer-level underfill (WLUF) material such that a combination of the off-eutectic material and the WLUF material includes at least one similar mechanical property of a eutectic material.

Example 21 may include the apparatus of example 20 and/or one or more other examples herein, wherein the at least one similar mechanical property of a eutectic material includes one or more of a shear strength, a tensile strength, a tensile elongation, shock performance, or a hardness.

Example 22 may include the apparatus of any one of examples 1-19 and/or one or more other examples herein, wherein the joint between the first substrate and the second substrate is an FLI joint, and wherein the solder is formed of a same off-eutectic material as another solder forming an MLI joint or an SLI joint, or the solder is formed of a different off-eutectic material than the other solder forming the MLI joint or the SLI joint.

Example 23 may include the apparatus of any one of examples 1-19 and/or one or more other examples herein, wherein the package is a ball grid array (BGA) package and the solder includes a plurality of solder balls, wherein the second substrate is soldered to the first substrate via the plurality of solder balls such that each solder ball of the plurality of solder balls forms a corresponding joint between the first substrate and the second substrate, and wherein each solder ball of the plurality of solder balls comprises the off-eutectic material, and wherein the corresponding joint formed by each solder ball of the plurality of solder balls is at least one of a first level interconnect (FLI) joint, a middle level interconnect (MLI) joint, or a second level interconnect (SLI) joint.

Example 24 may include the apparatus of any one of examples 1-19 and/or one or more other examples herein, wherein the package is a solder on die (SoD) package, wherein the second substrate is soldered to the first substrate via a plurality of solder-Cu bump connections such that each solder-Cu bump connection of the plurality of solder-Cu bump connections forms a corresponding joint between the first substrate and the second substrate, wherein the corresponding joint formed by each solder-Cu bump connection of the plurality of solder-Cu bump connections is a first level interconnect (FLI) joint, and wherein the package includes a WLUF material.

Example 25 may include the apparatus of any one of examples 1-19 and/or one or more other examples herein, wherein the package is a solder grid array (SGA) package, wherein the second substrate is soldered to the first substrate via a plurality of SGA bumps such that each SGA bump of the plurality of SGA bumps forms a corresponding joint between the first substrate and the second substrate, wherein the corresponding joint formed by each SGA bump of the plurality of SGA bumps is a first level interconnect (FLI) joint.

Example 26 may include a method comprising: heating a solder made of an off-eutectic material to a desired temperature, wherein the off-eutectic material is a material that melts over a range of melting temperatures; and coupling the heated solder to a substrate to form a joint between the package and the substrate. When the off-eutectic material is at a temperature that is above a greatest temperature of the range of melting temperatures, the off-eutectic material is in a molten state. When an off-eutectic material is at a temperature that is below a lowest temperature of the range of melting temperatures, the off-eutectic material is in a solid state.

Example 27 may include the method of example 26 and/or one or more other examples herein, further comprising: applying, to the joint, a wafer-level underfill (WLUF) material such that a combination of the off-eutectic material and the WLUF material includes at least one similar mechanical property of eutectic materials.

Example 28 may include the method of examples 26-27 and/or one or more other examples herein, wherein the at least one similar mechanical property of a eutectic material includes one or more of a shear strength, a tensile strength, a tensile elongation, shock performance, or a hardness.

Example 29 may include the method of examples 26-27 and/or one or more other examples herein, wherein the package is a solder on die (SoD) package, and the solder includes a plurality of solder bumps made of the off-eutectic material, and the method comprises: providing each of the plurality of solder bumps on top of a corresponding one of a plurality of Cu bumps of the package prior to the heating, wherein each of the plurality of solder bumps forms a corresponding joint between the SoD package and the substrate; coating a surface of the package with the WLUF material prior to the heating; and performing a solder reflow process after the coupling.

Example 30 may include the method of example 29 and/or one or more other examples herein, wherein the corresponding joint formed by each of the plurality of solder bumps is a first level interconnect (FLI) joint.

Example 31 may include the method of examples 26-27 and/or one or more other examples herein, wherein the package is a ball grid array (BGA) package and the solder includes a plurality of solder balls made of the off-eutectic material, wherein, the heating comprises heating the plurality of solder balls in a to BGA of the BGA package to a temperature greater than a greatest temperature of the melting range of temperatures of the off-eutectic material; and the coupling comprises coupling the plurality of solder balls to a substrate to form a plurality of solder joints between the BGA package and the substrate while the off-eutectic material is at the temperature greater than a greatest temperature of the range of melting temperatures, wherein the corresponding joints are FLI joints, middle level interconnect (MLI) joints, or second level interconnect (SLI) joints.

Example 32 may include the method of example 26 and/or one or more other examples herein, wherein the package is a solder grid array (SGA) package and the solder includes a plurality of SGA bumps made of the off-eutectic material, wherein, the heating comprises heating the plurality of SGA bumps in a SGA of the SGA package to a temperature greater than a greatest temperature of the range of melting temperatures of the off-eutectic material; and the coupling comprises coupling the plurality of SGA bumps to a substrate to form a plurality of solder joints between the SGA package and the substrate while the off-eutectic material is at the temperature greater than the greatest temperature of the range of melting temperatures, wherein the corresponding joints are FLI joints, MLI joints, or SLI joints.

Example 33 may include the method of any one of examples 26-32 and/or one or more other examples herein, wherein the off-eutectic material includes one or more of copper (Cu), tin (Sn), silver (Ag), bismuth (Bi), indium (In), lead (Pb), and zinc (Zn).

Example 34 may include the method of example 33 and/or one or more other examples herein, wherein the off-eutectic material includes a dopant, wherein the dopant includes one or more of Cu, Sn, Ag, Bi, In, Pb, Zn, nickel (Ni), chromium (Cr), titanium (Ti), yettrium (Ye), zirconium (Zr), antimony (Sb), strontium (Sr), cobalt (Co), iron (Fe), manganese (Mn), molybdeum (Mo), tungsten (W), platinum (Pt), gold (Au), magnesium (Mg), cerium (Ce), and lanthanum (La). In some examples, the dopant may include one or more other elements and/or materials not cited herein.

Example 35 may include the method of any one of examples 26-32 and/or one or more other examples herein, wherein the second substrate was soldered to the first substrate at a temperature greater than a greatest temperature of the range of melting temperatures.

Example 36 may include the method of any one of examples 26-32 and/or one or more other examples herein, wherein the off-eutectic material includes approximately 0.5-1.5% Ag and approximately 0.1-0.7% Cu, and wherein a lowest temperature of the range of melting temperatures is between approximately 215-220 degrees Celsius and a greatest temperature of the range of melting temperatures is between approximately 222-230 degrees Celsius.

Example 37 may include the method of example 36 and/or one or more other examples herein, wherein the off-eutectic material is doped with Ni.

Example 38 may include the method of any one of examples 26-32 and/or one or more other examples herein, wherein the off-eutectic material includes more than approximately 0.7% Cu, and wherein a lowest temperature of the range of melting temperatures is between approximately 225-229 degrees Celsius and a greatest temperature of the range of melting temperatures is between approximately 238-242 degrees Celsius.

Example 39 may include the method of any one of examples 26-32 and/or one or more other examples herein, wherein the off-eutectic material comprises a material having a greatest temperature of the range of melting temperatures that is less than or equal to approximately 250-260 degrees Celsius.

Example 40 may include the method of any one of examples 26-32 and/or one or more other examples herein, wherein the range of melting temperatures includes a liquidus range of temperatures and a solidus range of temperatures, wherein the off-eutectic material is completely liquid when the off-eutectic material is at a temperature above a greatest temperature of the range of liquidus temperatures and the off-eutectic material is completely solid when the off-eutectic material is at a temperature below a lowest temperature of the range of solidus temperatures.

Example 41 may include the method of example 40 and/or one or more other examples herein, wherein the off-eutectic material comprises approximately 60-80% Sn and approximately 20-40% Zn, wherein a lowest temperature of the range of liquidus temperatures is between approximately 225-230 degrees Celsius and a greatest temperature of the range of liquidus temperatures is between approximately 290-300 degrees Celsius, and wherein the off-eutectic material further comprises a range of solidus temperatures between approximately 197-200 degrees.

Example 42 may include the method of example 40 and/or one or more other examples herein, wherein the off-eutectic material comprises approximately 90-98% Sn and approximately 2-10% Zn, wherein a lowest temperature of the range of liquidus temperatures is between approximately 220-225 degrees Celsius and a greatest temperature of the range of liquidus temperatures is between approximately 227-230 degrees Celsius, and wherein the off-eutectic material further comprises a range of solidus temperatures between approximately 197-200 degrees Celsius.

Example 43 may include the method of example 40 and/or one or more other examples herein, wherein the off-eutectic material comprises approximately 60-80% Sn and approximately 20-50% Bi, wherein a lowest temperature of the range of liquidus temperatures is between approximately 150-160 degrees Celsius and a greatest temperature of the range of liquidus temperatures is between approximately 190-200 degrees Celsius, and wherein the off-eutectic material further comprises a range of solidus temperatures between approximately 137-139 degrees Celsius.

Example 44 may include the method of example 40 and/or one or more other examples herein, wherein the off-eutectic material comprises approximately 10-40% Sn and approximately 60-90% Bi, wherein a lowest temperature of the range of liquidus temperatures is between approximately 150-160 degrees Celsius and a greatest temperature of the range of liquidus temperatures is between approximately 240-250 degrees Celsius, and wherein the off-eutectic material further comprises a range of solidus temperatures between approximately 137-139 degrees Celsius.

Example 45 may include the method of example 40 and/or one or more other examples herein, wherein the off-eutectic material comprises approximately 20-50% Sn and approximately 50-80% Pb, wherein a lowest temperature of the range of liquidus temperatures is between approximately 200-210 degrees Celsius and a greatest temperature of the range of liquidus temperatures is between approximately 260-275 degrees Celsius, and wherein the off-eutectic material further comprises a range of solidus temperatures between approximately 182-184 degrees Celsius.

Example 46 may include the method of example 40 and/or one or more other examples herein, wherein the off-eutectic material comprises approximately 70-90% Sn and approximately 10-30% Pb wherein a lowest temperature of the range of liquidus temperatures is between approximately 200-210 degrees Celsius and a greatest temperature of the range of liquidus temperatures is between approximately 215-225 degrees Celsius, and wherein the off-eutectic material further comprises a range of solidus temperatures between approximately 182-184 degrees Celsius.

Example 47 may include the method of example 40 and/or one or more other examples herein, wherein the off-eutectic material comprises approximately 60-85% Sn and approximately 15-40% In, wherein a lowest temperature of the range of liquidus temperatures is between approximately 135-145 degrees Celsius and a greatest temperature of the range of liquidus temperatures is between approximately 190-200 degrees Celsius, and wherein the off-eutectic material further comprises a range of solidus temperatures between approximately 117-119 degrees Celsius.

Example 48 may include the method of example 40 and/or one or more other examples herein, wherein the off-eutectic material comprises approximately 90-95% Sn and approximately 5-10% Ag, wherein a lowest temperature of the range of liquidus temperatures is between approximately 230-240 degrees Celsius and a greatest temperature of the range of liquidus temperatures is between approximately 290-300 degrees Celsius, and wherein the off-eutectic material further comprises a range of solidus temperatures between approximately 220-222 degrees Celsius.

Example 49 may include the method of example 40 and/or one or more other examples herein, wherein the off-eutectic material comprises approximately 95-97% Sn and approximately 3-5% Cu, wherein a lowest temperature of the range of liquidus temperatures is between approximately 250-260 degrees Celsius and a greatest temperature of the range of liquidus temperatures is between approximately 290-300 degrees Celsius, and wherein the off-eutectic material further comprises a range of solidus temperatures between approximately 226-228 degrees Celsius.

Example 50 may include the method of example 40 and/or one or more other examples herein, wherein the off-eutectic material comprises approximately 60-90% Bi and approximately 10-40% In wherein a lowest temperature of the range of liquidus temperatures is between approximately 150-160 degrees Celsius and a greatest temperature of the range of liquidus temperatures is between approximately 240-250 degrees Celsius, and wherein the off-eutectic material further comprises a range of solidus temperatures between approximately 109-111 degrees Celsius.

1. An apparatus comprising:
a first substrate; and
a package that includes a second substrate soldered to the first substrate via solder comprising an off-eutectic material such that the solder forms a joint between the first substrate and the second substrate, wherein the off-eutectic material is a material that melts over a range of melting temperatures.

2. The apparatus of claim 1, wherein the off-eutectic material includes one or more of copper (Cu), tin (Sn), silver (Ag), bismuth (Bi), indium (In), lead (Pb), and zinc (Zn).

3. The apparatus of claim 2, wherein the off-eutectic material includes a dopant, wherein the dopant includes one or more of Cu, Sn, Ag, Bi, In, Pb, Zn, nickel (Ni), chromium (Cr), titanium (Ti), yettrium (Ye), zirconium (Zr), antimony (Sb), strontium (Sr), cobalt (Co), iron (Fe), manganese (Mn), molybdenum (Mo), tungsten (W), platinum (Pt), gold (Au), magnesium (Mg), cerium (Ce), and lanthanum (La).

4. The apparatus of claim 1, wherein the second substrate was soldered to the first substrate at a temperature greater than a greatest temperature of the range of melting temperatures.

5. The apparatus of claim 1, wherein the off-eutectic material includes approximately 0.5-1.5% Ag and approximately 0.1-0.7% Cu, and wherein a lowest temperature of the range of melting temperatures is between approximately 215-220 degrees Celsius and a greatest temperature of the range of melting temperatures is between approximately 222-230 degrees Celsius.

6. The apparatus of claim 5, wherein the off-eutectic material is doped with Ni.

7. The apparatus of claim 1, wherein the off-eutectic material includes more than approximately 0.7% Cu, and wherein a lowest temperature of the range of melting temperatures is between approximately 225-229 degrees Celsius and a greatest temperature of the range of melting temperatures is between approximately 238-242 degrees Celsius.

8. The apparatus of claim 1, wherein the off-eutectic material comprises a material having a greatest temperature of the range of melting temperatures that is less than or equal to approximately 250-260 degrees Celsius.

9. The apparatus of claim 1, wherein the range of melting temperatures includes a liquidus range of temperatures and a solidus range of temperatures, wherein the off-eutectic material is completely liquid when the off-eutectic material is at a temperature above a greatest temperature of the range of liquidus temperatures and the off-eutectic material is completely solid when the off-eutectic material is at a temperature below a lowest temperature of the range of solidus temperatures.

10. The apparatus of claim 9, wherein the off-eutectic material comprises approximately 60-80% Sn and approximately 20-40% Zn, wherein a lowest temperature of the range of liquidus temperatures is between approximately 225-230 degrees Celsius and a greatest temperature of the range of liquidus temperatures is between approximately 290-300 degrees Celsius, and wherein the off-eutectic material further comprises a range of solidus temperatures between approximately 197-200 degrees Celsius.

11. The apparatus of claim 9, wherein the off-eutectic material comprises approximately 90-98% Sn and approximately 2-10% Zn, wherein a lowest temperature of the range of liquidus temperatures is between approximately 220-225 degrees Celsius and a greatest temperature of the range of liquidus temperatures is between approximately 227-230 degrees Celsius, and wherein the off-eutectic material further comprises a range of solidus temperatures between approximately 197-200 degrees Celsius.

12. The apparatus of claim 9, wherein the off-eutectic material comprises approximately 60-80% Sn and approximately 20-50% Bi, wherein a lowest temperature of the range of liquidus temperatures is between approximately 150-160 degrees Celsius and a greatest temperature of the range of liquidus temperatures is between approximately 190-200 degrees Celsius, and wherein the off-eutectic material further comprises a range of solidus temperatures between approximately 137-139 degrees Celsius.

13. The apparatus of claim 9, wherein the off-eutectic material comprises approximately 10-40% Sn and approximately 60-90% Bi, wherein a lowest temperature of the range of liquidus temperatures is between approximately 150-160 degrees Celsius and a greatest temperature of the range of liquidus temperatures is between approximately 240-250 degrees Celsius, and wherein the off-eutectic material further comprises a range of solidus temperatures between approximately 137-139 degrees Celsius.

14. The apparatus of claim 9, wherein the off-eutectic material comprises approximately 20-50% Sn and approximately 50-80% Pb, wherein a lowest temperature of the range of liquidus temperatures is between approximately 200-210 degrees Celsius and a greatest temperature of the range of liquidus temperatures is between approximately 260-275 degrees Celsius, and wherein the off-eutectic material further comprises a range of solidus temperatures between approximately 182-184 degrees Celsius.

15. The apparatus of claim 9, wherein the off-eutectic material comprises approximately 70-90% Sn and approximately 10-30% Pb wherein a lowest temperature of the range of liquidus temperatures is between approximately 200-210 degrees Celsius and a greatest temperature of the range of liquidus temperatures is between approximately 215-225 degrees Celsius, and wherein the off-eutectic material further comprises a range of solidus temperatures between approximately 182-184 degrees Celsius.

16. The apparatus of claim 9, wherein the off-eutectic material comprises approximately 60-85% Sn and approximately 15-40% In, wherein a lowest temperature of the range of liquidus temperatures is between approximately 135-145 degrees Celsius and a greatest temperature of the range of liquidus temperatures is between approximately 190-200 degrees Celsius, and wherein the off-eutectic material further comprises a range of solidus temperatures between approximately 117-119 degrees Celsius.

17. The apparatus of claim 9, wherein the off-eutectic material comprises approximately 90-95% Sn and approximately 5-10% Ag, wherein a lowest temperature of the range of liquidus temperatures is between approximately 230-240 degrees Celsius and a greatest temperature of the range of liquidus temperatures is between approximately 290-300 degrees Celsius, and wherein the off-eutectic material further comprises a range of solidus temperatures between approximately 220-222 degrees Celsius.

18. The apparatus of claim 9, wherein the off-eutectic material comprises approximately 95-97% Sn and approximately 3-5% Cu, wherein a lowest temperature of the range of liquidus temperatures is between approximately 250-260 degrees Celsius and a greatest temperature of the range of liquidus temperatures is between approximately 290-300 degrees Celsius, and wherein the off-eutectic material further comprises a range of solidus temperatures between approximately 226-228 degrees Celsius.

19. The apparatus of claim 9, wherein the off-eutectic material comprises approximately 60-90% Bi and approximately 10-40% In wherein a lowest temperature of the range of liquidus temperatures is between approximately 150-160 degrees Celsius and a greatest temperature of the range of liquidus temperatures is between approximately 240-250 degrees Celsius, and wherein the off-eutectic material further comprises a range of solidus temperatures between approximately 109-111 degrees Celsius.

20. The apparatus of claim 1, wherein the solder joint includes a wafer-level underfill (WLUF) material such that a combination of the off-eutectic material and the WLUF material includes at least one similar mechanical property of a eutectic material, wherein the at least one similar mechanical property of a eutectic material includes one or more of a shear strength, a tensile strength, a tensile elongation, shock performance, or a hardness.

21. A method comprising:
heating a solder made of an off-eutectic material to a desired temperature, wherein the off-eutectic material is a material that melts over a range of melting temperatures; and
coupling the heated solder to a substrate to form a joint between the package and the substrate.

22. The method of claim 21, further comprising:
applying, to the joint, a wafer-level underfill (WLUF) material such that a combination of the off-eutectic material and the WLUF material includes at least one similar mechanical property of an eutectic material, wherein the at least one similar mechanical property of a eutectic material includes one or more of a shear strength, a tensile strength, a tensile elongation, shock performance, or a hardness.

23. The method of claim 21, wherein the package is a solder on die (SoD) package, and the solder includes a plurality of solder bumps made of the off-eutectic material, and the method comprises:
providing each of the plurality of solder bumps on top of a corresponding one of a plurality of Cu bumps of the package prior to the heating, wherein each of the plurality of solder bumps forms a corresponding joint between the SoD package and the substrate;
coating a surface of the package with the WLUF material prior to the heating; and
performing a solder reflow process after the coupling,
wherein the corresponding joint formed by each of the plurality of solder bumps is a first level interconnect (FLI) joint.

24. The method of claim 21, wherein the package is a ball grid array (BGA) package and the solder includes a plurality of solder balls made of the off-eutectic material, and wherein:
the heating comprises heating the plurality of solder balls in a BGA of the BGA package to a temperature greater than a greatest temperature of the range of melting temperatures of the off-eutectic material; and
the coupling comprises coupling the plurality of solder balls to a substrate to form a plurality of solder joints between the BGA package and the substrate while the off-eutectic material is at the temperature greater than a greatest lowest temperature of the range of melting temperatures,
wherein the corresponding joints are FLI joints, middle level interconnect (MLI) joints, or second level interconnect (SLI) joints.

25. The method of claim 21, wherein the package is a solder grid array (SGA) package and the solder includes a plurality of SGA bumps made of the off-eutectic material, and wherein:
the heating comprises heating the plurality of SGA bumps in a SGA of the SGA package to a temperature greater than a greatest temperature of the range of melting temperatures of the off-eutectic material; and
the coupling comprises coupling the plurality of SGA bumps to a substrate to form a plurality of solder joints between the SGA package and the substrate while the off-eutectic material is at the temperature greater than the greatest temperature of the range of melting temperatures,
wherein the corresponding joints are FLI joints, MLI joints, or SLI joints.
